(19) United States
(12) Patent Application Publication
(10) Pub. No.: US 2025/0348649 A1
(43) Pub. Date: Nov. 13, 2025

(54) SYSTEMS AND METHODS FOR OPTIMIZING LAYOUTS OF INTEGRATED CIRCUITS

(71) Applicant: Taiwan Semiconductor Manufacturing Company, Ltd., Hsinchu (TW)

(72) Inventors: Shang-Wei Fang, Hsinchu (TW); Jiann-Tyng Tzeng, Hsinchu (TW); Sheng-Feng Huang, Hsinchu (TW)

(73) Assignee: Taiwan Semiconductor Manufacturing Company, Ltd., Hsinchu (TW)

(21) Appl. No.: 19/275,335

(22) Filed: Jul. 21, 2025

Related U.S. Application Data
(63) Continuation of application No. 18/350,944, filed on Jul. 12, 2023.

(51) Int. Cl. G06F 30/392

(52) U.S. Cl. CPC G06F 30/392

(57) ABSTRACT

A semiconductor device includes: an area formed on a substrate and organized into a plurality of cell rows extending along a first direction; a first cell disposed across a first one of the plurality of cell rows, the first cell having a first height along a second direction perpendicular to the first direction; and a second cell disposed across a second one and half of a third one of the plurality of cell rows, the second cell having a second height. The first cell essentially consists of a first active region with a first conductivity and a second active region with a second conductivity. The second cell essentially consists of a third active region with the first conductivity and a fourth active region with the second conductivity. The second height is 1.5 times as high as the first height.

### CROSS-REFERENCE TO RELATED APPLICATION

The application is a continuation of U.S. patent application Ser. No. 18/350,944, filed Jul. 12, 2023, which is incorporated herein by reference in its entirety for all purposes.

### BACKGROUND

The semiconductor integrated circuit (IC) industry has experienced exponential growth. In semiconductor IC design, standard cell methodologies are commonly used for the design of semiconductor devices on a chip. Standard cell methodologies use standard cells as abstract representations of certain functions to integrate millions devices on a single chip. As ICs continue to scale down, more and more devices are integrated into the single chip. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example layout of an integrated circuit that include various cells, in accordance with some embodiments.

FIG. 2 illustrates another example layout of an integrated circuit, in accordance with some embodiments.

FIG. 3 illustrates yet another example layout of an integrated circuit, in accordance with some embodiments.

FIG. 4 illustrates a cross-sectional view of a portion of a semiconductor device formed based on the layout of FIG. 3, in accordance with some embodiments.

FIG. 5 illustrates yet another example layout of an integrated circuit that include various cells, in accordance with some embodiments.

FIG. 6 illustrates an example flow chart of a method for optimizing standard cell layout designs in integrated circuits, in accordance with some embodiments.

FIG. 7 illustrates an example computer system for implementing various embodiments of the present disclosure, in accordance with some embodiments.

FIG. 8 illustrates a process to form standard cell structures based on a graphic database system (GDS) file, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Standard cell structures can incorporate advanced transistor devices such as nanostructure (e.g., nanosheet) field-effect transistors (FETs). The standard cell structures can implement a one-fin (or one-channel) layout which includes one p-type FET and one n-type FET. Compared to a two-fin (or two-channel) layout which includes two p-type FETs and two n-type FETs, a one-fin layout is a more compact unit that provides improved layout flexibility and greater cell density.

In the layout of an integrated circuit, a plural number of such one-fin standard cell structures can be placed or otherwise arranged over the area of a substrate. Such a layout technique is sometimes referred to as “single height (SH)” cell. In accordance with advance of the technology node, various novel layout techniques have been proposed to increase speed of the corresponding integrated circuit, while maintaining the leakage current at a relatively low level. For example, along a vertical direction where at least three one-fin standard cell structures are arranged, the FETs with the same conductivity from different one-fin standard cell structures can merge, which equivalently transforms three FETs with a smaller size (e.g., a narrower channel width) to two FETs with a bigger size (e.g., a wider channel width). This technique is sometimes referred to as “PPNN” cell.

However, such layout techniques commonly trigger a trade-off between the speed/leakage and a packing density. Due to the process capability, the channel width cannot be unlimitedly increased, e.g., typically limited by a width threshold (Wₘₐₓ). Accordingly, the packing density (e.g., a total width of the channels divided by a corresponding cell height) is disadvantageously lower than solely using the one-fin standard cell structures. Further, in a layout with the coexistence of the SH cell and PPNN cell, a transition break between respective channels of the SH cell and the PPNN cell is frequently present, which can cause severe process issues. Thus, the existing layout techniques in advanced technology nodes have not been entirely satisfactory in some aspects.

The present disclosure provides various embodiments of a layout technique for forming an integrated circuit in advanced technology nodes that has improved speed, while maintaining its leakage at a relatively low level. Further, a packing density of the disclosed layout will not be sacrificed. In some aspects of the present disclosure, the disclosed layout includes placing, over the area of a substrate, one or more instances of a first cell that has a first channel with a first flexible width and a second channel with a second flexible width across 1.5 cell rows, and one or more instances of a second cell that has a third channel with a third width and a fourth channel with a fourth width across 1 cell row. By arranging the first cell across 1.5 cell rows, the first and second widths (Wₒ) can be flexibly increased to be equal to or greater than 1.5×W, where W represents the third/fourth width. As such, a packing density of the first cells (4Wₒ/3CH) can be flexibly adjusted to be equal to or greater than a packing density of the second cells (2W/CH), where CH represents a height of each of the cell rows. Further, based on adopting the first cells in the arrangement of a layout (which helps increase the packing density), a transition between the first cell and the second cell is allowed to be enlarged, e.g., about 2 to 3 units of a Contacted Poly Pitch (CPP), which can significantly reduce a break between the respective channels of the first and second cells. Still further, as the first and second widths of each of the first cell can be flexibly and respectively configured, various orientations of cells can be arranged for one layout.

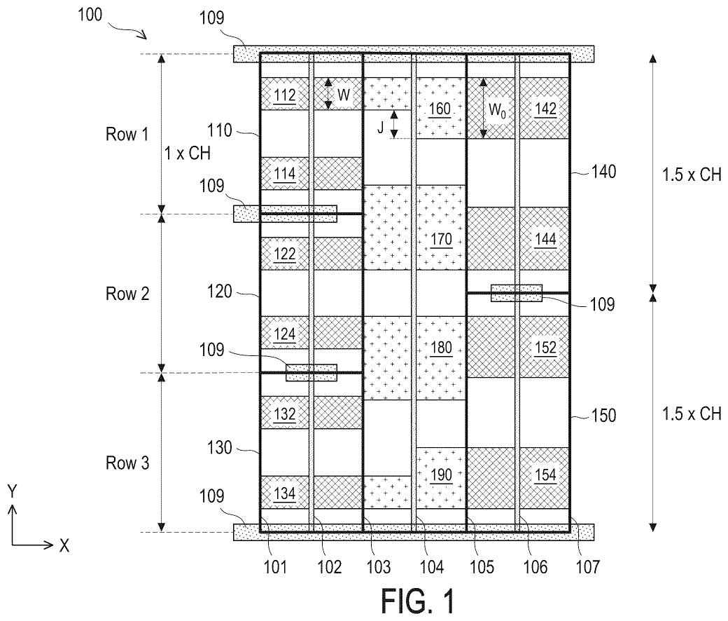

FIG. 1 illustrates an example layout 100 of an integrated circuit that incorporates various cells, according to some embodiments. The layouts (e.g., 100) illustrated in this disclosure can be standard cell layout or custom-designed cell layouts, from a library of cells. For example, the layout 100 may include a few pre-designed circuit blocks also referred to as standard cells. In some embodiments, the standard cells can be custom-designed cells. For simplicity and clarity purposes, FIG. 1 only illustrates cell boundaries of the standard cells, and other components of the standard cells are omitted. The layout 100 can further include patterns for any other suitable structures, for example, vias, conductive lines, dielectric layers, any other suitable structures, which are not shown in FIG. 1 for simplicity. A standard cell structure can include one or more standard cells from a standard cell library to perform a predetermined function in the integrated circuit, according to some embodiments. A standard cell can be any or all an AND, OR, XOR, XNOR, NAND, inverter, or other suitable logic device.

For example, the layout 100 includes instances of first cells 110, 120, and 130, and instances of second cells 140 and 150 each disposed across respective one(s) of multiple cell rows organized for an area of a substrate, e.g., ROW 1, ROW 2, and ROW 3. The cell rows each extend along a first lateral direction (e.g., the X-direction), and the cell rows each have a predefined cell height (CH) along a second lateral direction (e.g., the Y-direction). Specifically, the first cells 110 to 130 are each disposed over a respective one of the cell rows; and the second cells 140 and 150 are each disposed over a respective one of 1.5 cell rows. In FIG. 1, the first cell 110 is disposed over ROW 1; the first cell 120 is disposed over ROW 2; the first cell 130 is disposed over ROW 3; the second cell 140 is disposed over a whole ROW 1 and half of ROW 2; and the second cell 150 is disposed over half of ROW 2 and a whole ROW 3. Accordingly, the first cells 110 to 130 may each have a single CH; and the second cells 140 to 150 may each have a 1.5×CH. In some embodiments, an instance of the first cells 110 to 130 may be referred to as a single height (SH) cell, and an instance of the second cells 140 and 150 may be referred to as a one-half height (OHH) PPNN cell.

Further, each of the cells 110 to 150 can have a first active region and a second active region extending along the X-direction, in which the first active region and the second reign have respectively different conductivities. Such an active region may be utilized to define the channel of a corresponding FET, in some embodiments. In the embodiment where the FET is configured as a nanosheet transistor, the active region may be utilized to form a three-dimensional structure protruding from the substrate and having plural different compositions of semiconductor layers alternately disposed on top of one another. In the embodiment where the FET is configured as a fin-like transistor, the active region may be utilized to form a three-dimensional structure protruding from the substrate and having a semiconductor material identical to the substrate. Still further, each of the cells 110 to 150 can have respective segments of a number of gate structures extending along the Y-direction. The gate structures are parallel with each other, with a spacing between neighboring gate structures sometimes referred to as a Contacted Poly Pitch (CPP). Such a gate structure can traverse the corresponding active region to define a corresponding FET. Each of the gate structures can be cut, separated, or otherwise divided into a number of segments by one or more dielectric structures 109 (sometimes referred to as “Cut Poly (CPO)” structures).

For example in FIG. 1, the first cell 110 has a first active region 112 in n-type and a second active region 114 in p-type, with segments of a gate structure 102 traversing the active regions 112-114; the first cell 120 has a first active region 122 in p-type and a second active region 124 in n-type, with segments of the gate structure 102 traversing the active regions 122-124; the first cell 130 has a first active region 132 in n-type and a second active region 134 in p-type, with segments of the gate structure 102 traversing the active regions 132-134; the second cell 140 has a first active region 142 in n-type and a second active region 144 in p-type, with segments of a gate structure 106 traversing the active regions 142-144; and the second cell 150 has a first active region 152 in n-type and a second active region 154 in p-type, with segments of the gate structure 106 traversing the active regions 152-154.

Extending between the respective active regions of the first and second cells, the layout 100 further includes a dummy region. For example, between the active region 112 of the first cell 110 and the active region 142 of the second cell 140 along the X-direction, the layout 100 includes dummy region 160; between the active region 114 of the first cell 110 (also the active region 122 of the first cell 120) and the active region 144 of the second cell 140 along the X-direction, the layout 100 includes dummy region 170; between the active region 124 of the first cell 120 (also the active region 132 of the first cell 130) and the active region 152 of the second cell 150 along the X-direction, the layout 100 includes dummy region 180; and between the active region 134 of the first cell 130 and the active region 154 of the second cell 150 along the X-direction, the layout 100 includes dummy region 190.

In accordance with various embodiments of the present disclosure, the active regions 112 to 134 of the first cells each have a width (W) extending in the Y-direction; and the active regions 142 to 154 of the second cells each have a width (Wₒ) extending in the Y-direction. To reach an optimal packing density, the width Wₒ can be adjusted between 1.5×W and Wₘₐₓ (i.e., 1.5W≤Wₒ≤Wₘₐₓ), where Wₘₐₓ represents a maximum channel width that is allowed for a certain technology node. As such, a packing density corresponding to the first cell can be expressed as 2W/CH, and a packing density corresponding to the second cell can be expressed as 2Wₒ/1.5CH or 4Wₒ/3CH, which is in the range between 2W/CH and 4Wmax/3CH. Further, the width Wₒ may have a relationship with the width W, e.g., Wₒ=W+J×n, where J is a jogging distance transitioning from a smaller region width to a greater region width (as shown in FIG. 1) and n is an integer. In some embodiments, the jogging distance J is equal to or less than about 25 nanometers (nm), and n is equal to or greater than 1.

Given the increased packing density by implementing the instances of second cells (e.g., 140, 150) in the layout, the dummy regions (between the instance of first cell and the instance of second cell) can be alleviated to extend across a wider region along the X-direction, e.g., 2 times CPPs as shown in the example of FIG. 1. Such a 2×CPP may be referred to as a sum of one CPP between gate structures 103 and 104 and one CPP between gate structures 104 and 105. Such a dummy region is sometimes referred to as a “padding filler.” The extended dummy regions can significantly reduce the likelihood of any active region being abruptly disconnected from a dummy region (sometimes referred to as “oxide diffusion break”). It should be understood that the dummy region can extend across any number of CPPs depending on the width difference of connected active regions, while remaining within the scope of the present disclosure. For example, the dummy region may extend across 1×CPP. In another example, the dummy region may extend across 3×CPP.

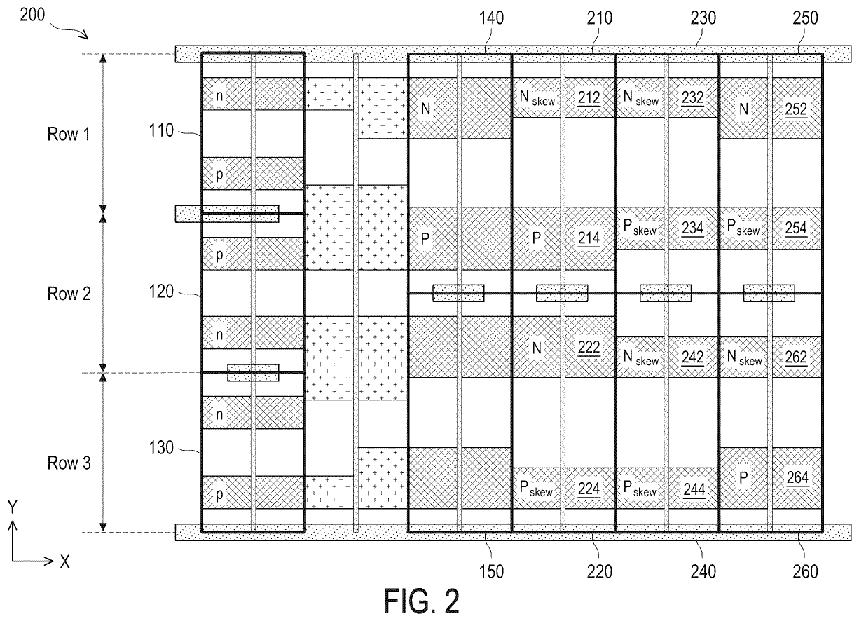

FIG. 2 illustrates another example layout 200 of an integrated circuit that incorporates various cells, according to some embodiments. The layout 200 is substantially similar to the layout 100 of FIG. 1 except that the layout 200 further includes various other instances of the second cells, e.g., 210, 220, 230, 240, 250, and 260. Each of the second cells 210 to 260 extends across 1.5 cell rows (i.e., having a height of 1.5×CH). Further, each of the second cells 210 to 260 has a first active region and a second active region with respectively different conductivities.

For example, the second cell 210 has a first active region 212 in n-type and a second region 214 in p-type; the second cell 220 has a first active region 222 in n-type and a second region 224 in p-type; the second cell 230 has a first active region 232 in n-type and a second region 234 in p-type; the second cell 240 has a first active region 242 in n-type and a second region 244 in p-type; the second cell 250 has a first active region 252 in n-type and a second region 254 in p-type; and the second cell 260 has a first active region 262 in n-type and a second region 264 in p-type.

Different from the second cells 140-150, the first and second active regions of each of the second cells 210, 220, 250, and 260 have respectively different widths (along the Y-direction). In the second cell 210, the p-type active region 214 is wider than the n-type active region 212; in the second cell 220, the n-type active region 222 is wider than the p-type region 224; in the second cell 250, the n-type active region 252 is wider than the p-type active region 254; and in the second cell 260, the p-type active region 264 is wider than the n-type active region 262. Similar to second cells 140-150, the first and second active regions of each of the second cells 230 and 240 have the same widths (along the Y-direction). In the second cell 230, the n-type active region 232 has the same width as the p-type active region 234; and in the second cell 240, the n-type active region 242 has the same width as the p-type active region 244. Regardless of having the same or different widths, the width of an active region of any instance of the disclosed second cell is equal to or greater than 1.5×W, in accordance with various embodiments.

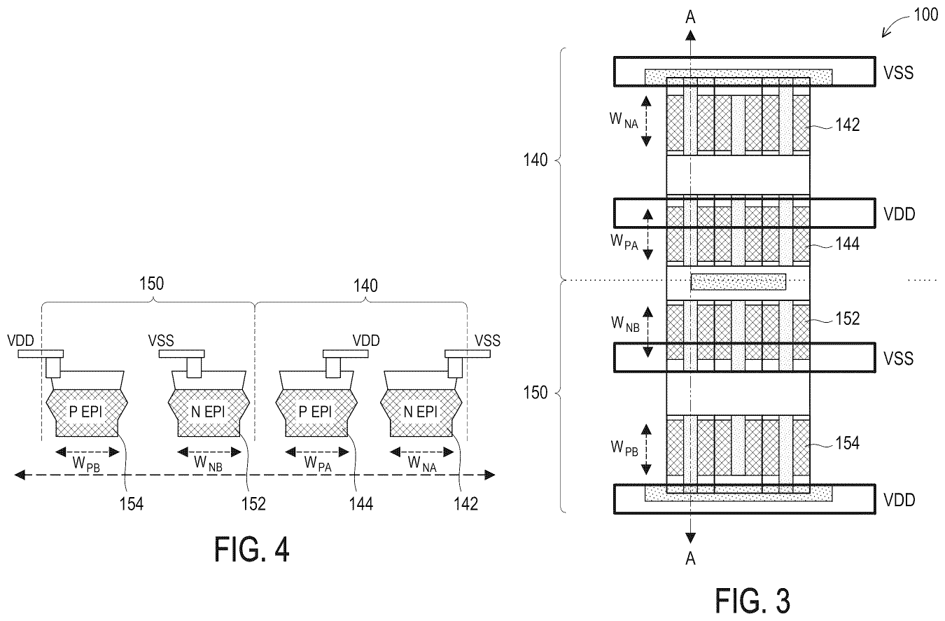

Referring now to FIG. 3, the layout 100 may further include a number of patterns configured to form interconnect structures operatively coupled to the second cells 140 and 150. For example in FIG. 3, the layout 100 further includes two sets of interconnect structures operatively functioning as power rails, VDD and VSS, one of which extend over the second cell 140, and the other of which extend over the second cell 150. The VSS power rail is configured to carry VSS supply voltage to a corresponding cell; and the VDD power rail is configured to carry VDD supply voltage to a corresponding cell. In some embodiments, each of the power rails, VDD or VSS, is formed to align the interface or edge between adjacent cell rows. As such, each of the instances of first cells 110 to 130 (not shown in FIG. 3) can have both of its opposite edges aligned with a respective set of VDD and VSS, and each of the instances of second cells 140 and 150 can have only edge aligned with either VDD or VSS.

For example in FIG. 3, the second cell 140 has its upper edge aligned with one of the VSS power rails, while a portion of its active region 144 outwardly protrudes from the corresponding VDD power rail; and the second cell 150 has its lower edge aligned with one of the VDD power rails, while a portion of its active region 152 outwardly protrudes from the corresponding VSS power rail. In other words, each of the instances of second cells can have one of its edges aligned with either a VSS or VDD power rail, and the other edge outwardly offset from the corresponding VDD or VSS power rail.

FIG. 4 illustrates a cross-sectional view of a portion of a semiconductor device formed based on the layout 300. The cross-sectional view of FIG. 4 is cut along line A-A shown in FIG. 3. As shown, the active regions 142 to 154 are each formed as an epitaxial region (or the source/drain of a corresponding FET) coupled to a VDD or VSS power rail through a middle-end interconnect structure (sometimes referred to as a “Metal Define (MD) structure”). As indicated, each of the active regions (or epitaxial regions) can have a respective width (along the cut direction, i.e., the Y-direction). For example, the active region 142 has a width W_{NA}; the active region 144 has a width W_{PA}; the active region 152 has a width W_{NB}; and the active region 154 has a width W_{PB}. In some embodiments, when the two instances of the second cell 140 and 150 are configured to have close or similar performance characteristics (e.g., timing, speed, etc.), the width W_{PA} may be substantially equal to width W_{PB}; and the width WA may be substantially equal to width W_{NB}.

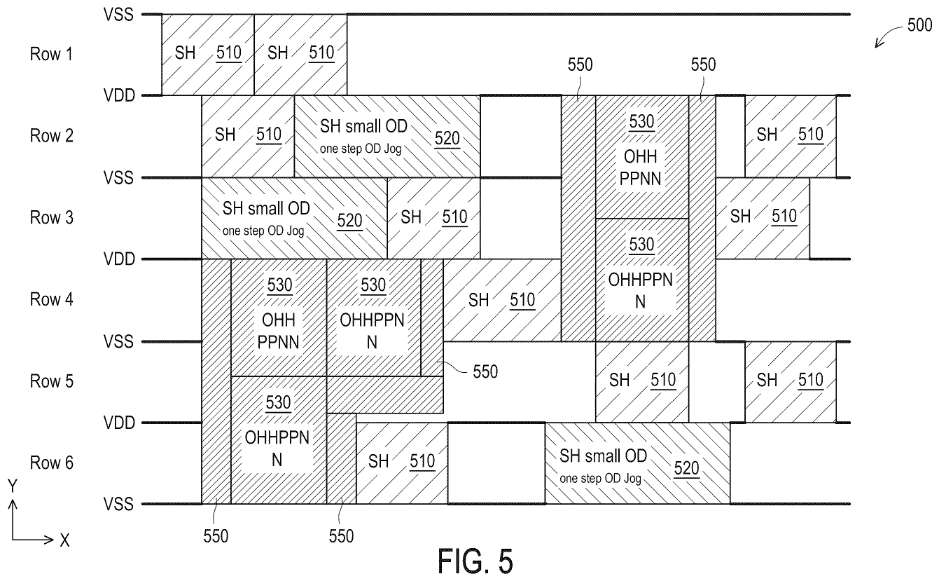

FIG. 5 illustrates yet another example layout 500 of an integrated circuit that incorporates various cells, according to some embodiments. As shown, the layout 500 includes multiple instances of one SH cell 510, multiple instances of another SH cell 520, and multiple instances of OHHPPNN cells 530, disposed across cell rows, ROW 1, ROW 2, ROW 3, ROW 4, ROW 5, and ROW 6. As discussed above, the SH cell (e.g., 510, 520) is disposed across 1 cell row, and the OHHPPNN cell (e.g., 530) is disposed across 1.5 cell rows. Further, the layout 500 can include one or more padding fillers (e.g., 550), each horizontally extending across 2×CPP, between an instance of SH cell and an instance of OHHPPNN cell.

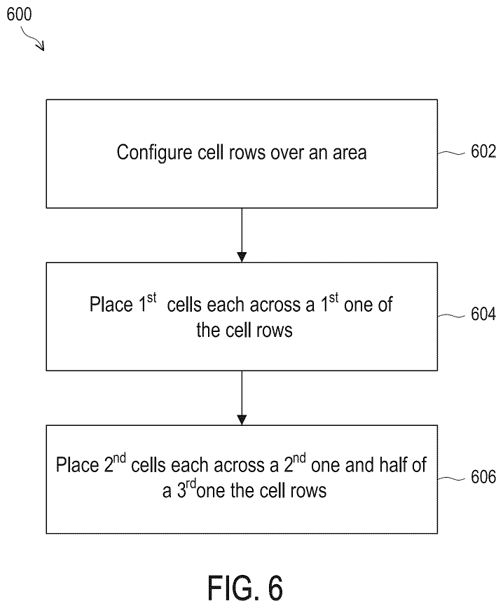

FIG. 6 illustrates a method 600 for optimizing standard cell layout designs in integrated circuits, according to some embodiments. Operations of method 600 can also be performed in a different order and/or vary. Variations of method 600 should also be within the scope of the present disclosure.

The method 600 starts with operation 602 in which a plurality of cell rows, each of the plurality of cell rows extending along a first direction, are configured over an area formed on a substrate. Using the layout 100 of FIG. 1 as a representative example, the cell rows, ROW 1, ROW 2, and ROW 3, may be configured as virtual racks over a given area of a substrate designated for a corresponding integrated circuit. Each of the cells extends along a first lateral direction, and has a cell height (CH) extending along a second lateral direction perpendicular to the first lateral direction.

The method 600 proceeds to operation 604 in which one or more instances of a first cell are each placed across a first one of the plurality of cell rows. Accordingly, the first cell has a first height equal to/x CH, and is formed of a first active region with a first conductivity and a second active region with a second conductivity. Continuing with the above example, multiple instances of the first cells, 110 to 130, are each placed across a respective cell row. Further, each of the first cells 110 to 130 has a first active region in n-type and a second active region in p-type, in which the first/second active region has a width (W) extending along the second lateral direction.

The method 600 proceeds to operation 606 in which one or more instances of a second cell are each placed across a second one and half of a third one of the plurality of cell rows. Accordingly, the second cell has a second height equal to 1.5×CH, and is formed of a third active region with the first conductivity and a fourth active region with the second conductivity. Still continuing with the above example, multiple instances of the second cells, 140 to 150, are each placed across a respective 1.5 cell rows. Further, each of the second cells 140 to 150 has a third active region in n-type and a fourth active region in p-type, in which the third/fourth active region has a width (Wₒ) extending along the second lateral direction.

In some embodiments of the present disclosure, the width Wₒ is equal to or greater than 1.5×W. In some embodiments of the present disclosure, the width Wₒ is equal to W+J×n, where J is equal to or less than 25 nanometers (nm) and n is an integer equal to or greater than 1.

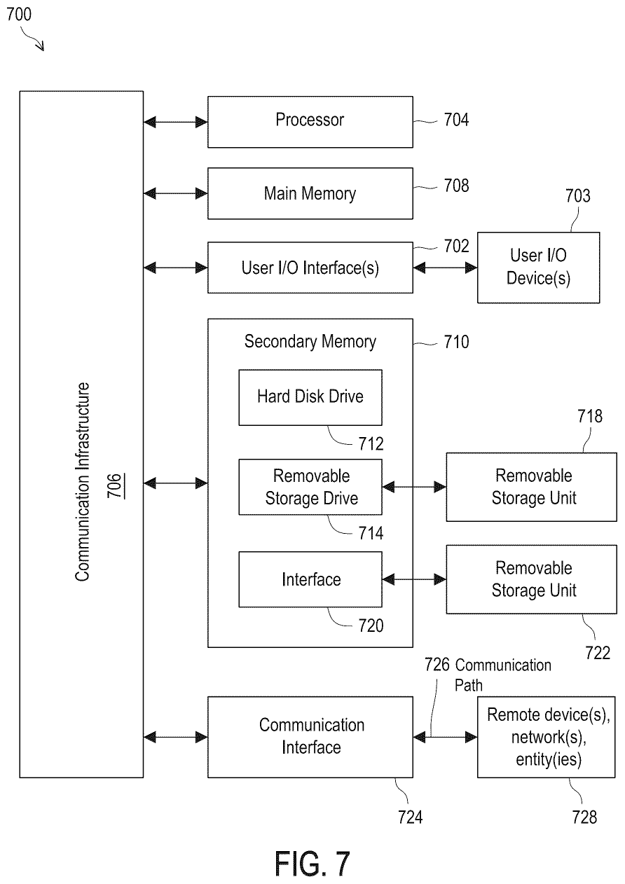

FIG. 7 is an illustration of an example computer system 700 in which various embodiments of the present disclosure can be implemented, according to some embodiments. Computer system 700 can be any well-known computer capable of performing the functions and operations described herein. For example, and without limitation, computer system 700 can be capable of selecting various standard cells to be optimized and placing those standard cells at desired locations, for example, an EDA tool. Computer system 700 can be used, for example, to execute one or more operations in the method 600.

Computer system 700 includes one or more processors (also called central processing units, or CPUs), such as a processor 704. Processor 704 is connected to a communication infrastructure or bus 706. Computer system 700 also includes input/output device(s) 703, such as monitors, keyboards, pointing devices, etc., that communicate with communication infrastructure or bus 706 through input/output interface(s) 702. An EDA tool can receive instructions to implement functions and operations described herein e.g., the method 600 of FIG. 6—via input/output device(s) 703. Computer system 700 also includes a main or primary memory 708, such as random access memory (RAM). Main memory 708 can include one or more levels of cache. Main memory 708 has stored therein control logic (e.g., computer software) and/or data. In some embodiments, the control logic (e.g., computer software) and/or data can include one or more of the operations described above with respect to the method 600 of FIG. 6.

Computer system 700 can also include one or more secondary storage devices or memory 710. Secondary memory 710 can include, for example, a hard disk drive 712 and/or a removable storage device or drive 714. Removable storage drive 714 can be a floppy disk drive, a magnetic tape drive, a compact disk drive, an optical storage device, tape backup device, and/or any other storage device/drive.

Removable storage drive 714 can interact with a removable storage unit 718. Removable storage unit 718 includes a computer usable or readable storage device having stored thereon computer software (control logic) and/or data. Removable storage unit 718 can be a floppy disk, magnetic tape, compact disk, DVD, optical storage disk, and/any other computer data storage device. Removable storage drive 714 reads from and/or writes to removable storage unit 718.

According to some embodiments, secondary memory 710 can include other means, instrumentalities or other approaches for allowing computer programs and/or other instructions and/or data to be accessed by computer system 700. Such means, instrumentalities or other approaches can include, for example, a removable storage unit 722 and an interface 720. Examples of the removable storage unit 722 and the interface 720 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, secondary memory 710, removable storage unit 718, and/or removable storage unit 722 can include one or more of the operations described above with respect to the method 600 of FIG. 6.

Computer system 700 can further include a communication or network interface 724. Communication interface 724 enables computer system 700 to communicate and interact with any combination of remote devices, remote networks, remote entities, etc. (individually and collectively referenced by reference number 728). For example, communication interface 724 can allow computer system 700 to communicate with remote devices 728 over communications path 726, which can be wired and/or wireless, and which can include any combination of LANs, WANs, the Internet, etc. Control logic and/or data can be transmitted to and from computer system 700 via communication path 726.

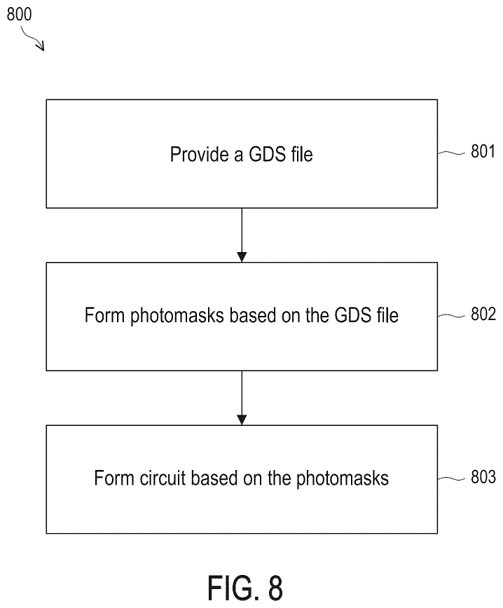

The operations in the preceding embodiments can be implemented in a wide variety of configurations and architectures. Therefore, some or all of the operations in the preceding embodiments e.g., the method 600 of FIG. 6 and method 800 of FIG. 8 (described below) can be performed in hardware, in software or both. In some embodiments, a tangible apparatus or article of manufacture comprising a tangible computer useable or readable medium having control logic (software) stored thereon is also referred to herein as a computer program product or program storage device. This includes, but is not limited to, computer system 700, main memory 708, secondary memory 710 and removable storage units 718 and 722, as well as tangible articles of manufacture embodying any combination of the foregoing. Such control logic, when executed by one or more data processing devices (such as computer system 700), causes such data processing devices to operate as described herein. In some embodiments, computer system 700 is installed with software to perform operations in the manufacturing of photomasks and circuits, as illustrated in method 800 of FIG. 8 (described below). In some embodiments, computer system 700 includes hardware/equipment for the manufacturing of photomasks and circuit fabrication. For example, the hardware/equipment can be connected to or be part of element 728 (remote device(s), network(s), entity(ies)) of computer system 700.

FIG. 8 is an illustration of an exemplary method 800 for circuit fabrication, according to some embodiments. Operations of method 800 can also be performed in a different order and/or vary. Variations of method 800 should also be within the scope of the present disclosure.

In operation 801, a GDS file is provided. The GDS file can be generated by an EDA tool and contain the standard cell structures that have already been optimized using the disclosed method. The operation depicted in 801 can be performed by, for example, an EDA tool that operates on a computer system, such as computer system 700 described above.

In operation 802, photomasks are formed based on the GDS file. In some embodiments, the GDS file provided in operation 801 is taken to a tape-out operation to generate photomasks for fabricating one or more integrated circuits. In some embodiments, a circuit layout included in the GDS file can be read and transferred onto a quartz or glass substrate to form opaque patterns that correspond to the circuit layout. The opaque patterns can be made of, for example, chromium or other suitable metals. Operation 802 can be performed by a photomask manufacturer, where the circuit layout is read using a suitable software (e.g., EDA tool) and the circuit layout is transferred onto a substrate using a suitable printing/deposition tool. The photomasks reflect the circuit layout/features included in the GDS file.

In operation 803, one or more circuits are formed based on the photomasks generated in operation 802. In some embodiments, the photomasks are used to form patterns/structures of the circuit contained in the GDS file. In some embodiments, various fabrication tools (e.g., photolithography equipment, deposition equipment, and etching equipment) are used to form features of the one or more circuits.

In one aspect of the present disclosure, a semiconductor device is disclosed. The semiconductor device includes: an area formed on a substrate and organized into a plurality of cell rows extending along a first direction; a first cell disposed across a first one of the plurality of cell rows, the first cell having a first height along a second direction perpendicular to the first direction; and a second cell disposed across a second one and half of a third one of the plurality of cell rows, the second cell having a second height. The first cell essentially consists of a first active region with a first conductivity and a second active region with a second conductivity. The second cell essentially consists of a third active region with the first conductivity and a fourth active region with the second conductivity. The second height is 1.5 times as high as the first height.

In another aspect of the present disclosure, a semiconductor device is disclosed. The semiconductor device includes: a first cell essentially consisting of a first active region with a first conductivity and a second active region with a second conductivity, the first and second active region both extending along a first direction; and a second cell essentially consisting of a third active region with the first conductivity and a fourth active region with the second conductivity, the third and fourth active region both extending along the first direction. The first cell has a first height along a second direction perpendicular to the first direction, and the second cell has a second height along the second direction. The second height is 1.5 times as high as the first height.

In yet another aspect of the present disclosure, a method of generating a layout, the layout being stored on a non-transitory computer-readable medium, the method includes: configuring, over an area formed on a substrate, a plurality of cell rows, each of the plurality of cell rows extending along a first direction; placing a first cell across a first one of the plurality of cell rows, the first cell, having a first height along a second direction perpendicular to the first direction, that is formed of a first active region with a first conductivity and a second active region with a second conductivity; and placing a second cell across a second one and half of a third one of the plurality of cell rows, the second cell, having a second height along the second direction, that is formed of a third active region with the first conductivity and a fourth active region with the second conductivity. The second height is 1.5 times as high as the first height.

As used herein, the terms “about” and “approximately” indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

As used herein, the term “substantially” indicates that the value of a given quantity varies by ±1% to ±5% of the value.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first cell comprising a first active region extending along a first direction and having a first conductivity and a second active region extending along the first direction and having a second conductivity, wherein the first cell has a first height along a second direction perpendicular to the first direction;
a second cell comprising a third active region extending along the first direction and having the first conductivity and a fourth active region extending along the first direction and having the second conductivity, wherein the second cell has a second height along the second direction; and
one or more dummy regions interposed between the first cell and the second cell along the first direction;
wherein the second height is 1.5 times as high as the first height.

2. The semiconductor device of claim 1, wherein each of the first active region and the second active region have a first width (W) along the second direction, and each of the third active region and the fourth active region have a second width (Wₒ) along the second direction, and wherein Wₒ is equal to or greater than 1.5×W.

3. The semiconductor device of claim 1, wherein each of the first active region and the second active region have a first width (W) along the second direction, and each of the third active region and the fourth active region have a second width (Wₒ) along the second direction, and wherein Wₒ is equal to W+J×n, where J is equal to or less than 25 nanometers (nm) and n is an integer equal to or greater than 1.

4. The semiconductor device of claim 1, wherein at least one of the one or more dummy regions has a single width that extends along the second direction.

5. The semiconductor device of claim 1, wherein at least one of the one or more dummy regions has multiple widths that each extend along the second direction.

6. The semiconductor device of claim 1, wherein each of the one or more dummy regions extend along the first direction across two units of a Contacted Poly Pitch (CPP).

7. The semiconductor device of claim 1, further comprising:
a plurality of first power rails extending along the first direction; and
a plurality of second power rails extending along the first direction;
wherein each of the plurality of first power rails and a corresponding one of the plurality of second power rails are disposed along edges of the first cell or the second cell.

8. The semiconductor device of claim 1, wherein the first conductivity is opposite to the second conductivity.

9. The semiconductor device of claim 1, wherein the first cell is disposed on a first one of a plurality of cell rows that extend along the first direction, and the second cell is disposed on a second one of the plurality of cell rows and further on a portion of a third one of the plurality of cell rows.

10. The semiconductor device of claim 9, wherein the first cell row and the second cell row are the same, with the third cell row arranged immediately next to the first or second cell row in the second direction.

11. The semiconductor device of claim 9, wherein the first cell row and the second cell row are different, with the third cell row arranged immediately next to the second cell row in the second direction.

12. A semiconductor device, comprising:
a first cell comprising a first active region extending along a first direction and having a first conductivity and a second active region extending along the first direction and having a second conductivity, wherein the first cell has a first height along a second direction perpendicular to the first direction;
a pair of first power rails extending along the first direction and respectively disposed along opposite edges of the first cell;
a second cell comprising a third active region extending along the first direction and having the first conductivity and a fourth active region extending along the first direction and having the second conductivity, wherein the second cell has a second height along the second direction; and
a pair of second power rails extending along the first direction and respectively disposed along opposite edges of the second cell;
wherein the second height is 1.5 times as high as the first height.

13. The semiconductor device of claim 12, wherein each of the first active region and the second active region have a first width (W) along the second direction, and each of the third active region and the fourth active region have a second width (Wₒ) along the second direction, and wherein Wₒ is equal to or greater than 1.5×W.

14. The semiconductor device of claim 12, wherein each of the first active region and the second active region have a first width (W) along the second direction, and each of the third active region and the fourth active region have a second width (Wₒ) along the second direction, and wherein Wₒ is equal to W+J×n, where J is equal to or less than 25 nanometers (nm) and n is an integer equal to or greater than 1.

15. The semiconductor device of claim 12, further comprising:
a dummy region interposed between the first cell and the second cell along the first direction.

16. The semiconductor device of claim 15, wherein the dummy region has a single width that extends along the second direction.

17. The semiconductor device of claim 15, wherein the dummy region has multiple widths that each extend along the second direction.

18. The semiconductor device of claim 15, wherein the dummy region extends along the first direction across two units of a Contacted Poly Pitch (CPP).

19. A semiconductor device, comprising:
a first cell comprising a first active region extending along a first direction and having a first conductivity and a second active region extending along the first direction and having a second conductivity, wherein the first cell has a first height along a second direction perpendicular to the first direction;
a pair of first power rails extending along the first direction and respectively disposed along opposite edges of the first cell;
a second cell comprising a third active region extending along the first direction and having the first conductivity and a fourth active region extending along the first direction and having the second conductivity, wherein the second cell has a second height along the second direction;
a pair of second power rails extending along the first direction and respectively disposed along opposite edges of the second cell; and
a dummy region interposed between the first cell and the second cell along the first direction;
wherein the second height is 1.5 times as high as the first height.

20. The semiconductor device of claim 19, wherein the dummy region extends along the first direction across two units of a Contacted Poly Pitch (CPP).
